(19) United States
(12) Patent Application Publication
(10) Pub. No.: US 2015/0159264 A1
(43) Pub. Date: Jun. 11, 2015

(54) SPUTTER DEPOSITION METHOD, SPUTTERING SYSTEM, MANUFACTURE OF PHOTOMASK BLANK, AND PHOTOMASK BLANK

(71) Applicant: Shin-Etsu Chemical Co., Ltd., Tokyo (JP)

(72) Inventors: Kouhei SASAMOTO, Joetsu-shi (JP); Souichi FUKAYA, Joetsu-shi (JP); Hideo NAKAGAWA, Joetsu-shi (JP); Yukio INAZUKI, Joetsu-shi (JP)

(73) Assignee: Shin-Etsu Chemical Co., Ltd., Tokyo (JP)

(21) Appl. No.: 14/561,311

(22) Filed: Dec. 5, 2014

(30) Foreign Application Priority Data
Dec. 6, 2013 (JP) 2013-253099

(51) Int. Cl. C23C 14/34; H01J 37/34; G03F 1/68

(52) U.S. Cl. CPC C23C 14/3464; G03F 1/68; H01J 37/3417; H01J 37/3441

(57) ABSTRACT

A film is sputter deposited on a substrate by providing a vacuum chamber (3) with first and second targets (1, 2) such that the sputter surfaces (11, 21) of the first and second targets (1, 2) may face the substrate (5) and be arranged parallel or oblique to each other, simultaneously supplying electric powers to the first and second targets (1, 2), and depositing sputtered particles on the substrate while controlling sputtering conditions such that the rate at which sputtered particles ejected from one target reach the sputter surface of the other target and deposit thereon is not more than the rate at which the sputtered particles are removed from the other target by sputtering.

### CROSS-REFERENCE TO RELATED APPLICATION

This non-provisional application claims priority under 35 U.S.C. §119(a) on Patent Application No. 2013-253099 filed in Japan on Dec. 6, 2013, the entire contents of which are hereby incorporated by reference.

### TECHNICAL FIELD

This invention relates to a sputter deposition method using a co-sputtering technique of simultaneously sputtering two or more targets, a sputtering system suited for use therein, a method of manufacturing a photomask blank having a functional film deposited on a transparent substrate, using the sputter deposition method or sputtering system, and a photomask blank manufactured using the sputter deposition method or sputtering system.

### BACKGROUND ART

In the semiconductor technology field, research and development efforts are continued for further reducing the pattern feature size. A challenge to higher integration of large-scale integrated circuits places an increasing demand for miniaturization of circuit patterns. There are increasing demands for further reduction in size of circuit-constructing wiring patterns and for miniaturization of contact hole patterns for cell-constructing inter-layer connections. As a consequence, in the manufacture of circuit pattern-bearing photomasks for use in the photolithography of forming such wiring patterns and contact hole patterns, a technique capable of accurately writing finer circuit patterns is needed to meet the miniaturization demand.

When a pattern is formed on a semiconductor substrate by photolithography, reduction projection is often used. Thus the photomask bears a pattern with a size which is about 4 times the size of the pattern formed on the semiconductor substrate. However, this does not mean that the accuracy required for the pattern formed on the photomask is loosened as compared with the pattern formed on the semiconductor substrate. The pattern formed on the photomask serving as an original is rather required to have a higher accuracy than the actual pattern formed following exposure.

Further, in the currently prevailing photolithography, a circuit pattern to be written has a feature size far smaller than the wavelength of light used. If a photomask is provided with a pattern which is a mere 4-time magnification of the size of the circuit pattern on the semiconductor substrate, a desired shape corresponding to the photomask pattern is not transferred to the resist film owing to influences such as optical interference during exposure.

To mitigate such influences as optical interference, in some cases, the photomask pattern must be designed to a shape which is more complex than the actual pattern. For example, such a shape is designed by applying the optical proximity correction (OPC) to the actual circuit pattern.

In conjunction with the miniaturization of circuit pattern size, the lithography technology for obtaining photomask patterns also requires a higher accuracy processing method. The lithographic performance is sometimes represented by a maximum resolution. As mentioned above, the pattern formed on the photomask serving as an original is required to have a higher accuracy than the actual pattern formed following exposure.

From a photomask blank having a light-shielding film on a transparent substrate, a photomask pattern is generally formed by coating a resist film on the blank, and writing a pattern using electron beam, i.e., exposure. The exposed resist film is developed to form a resist pattern. With the resulting resist pattern made an etch mask, the light-shielding film is then etched into a light-shielding film pattern. The light-shielding film pattern becomes a photomask pattern.

At this point, the thickness of resist film must be reduced in harmony with the degree of miniaturization of light-shielding pattern. In an attempt to form a fine light-shielding pattern while maintaining the thickness of the resist film unchanged, the ratio of resist film thickness to light-shielding pattern size, known as aspect ratio, becomes greater. As a result, the resist pattern profile is degraded to prevent effective pattern transfer. In some cases, the resist film pattern will collapse or strip off.

As the material of the light-shielding film formed on a transparent substrate, many materials have been proposed thus far. In practice, chromium compounds are used by reason that their etching behavior is well known. Dry etching of chromium-based material film is generally chlorine-based dry etching. The chlorine-based dry etching, however, often has an etching ability of certain level relative to organic films. For this reason, when a pattern is formed in a thin resist film, and a light-shielding film is etched with the resist pattern made etch mask, the resist pattern can also be etched to a non-negligible extent by the chlorine-based dry etching. As a result, the desired resist pattern to be transferred to the light-shielding film is not accurately transferred.

To avoid such inconvenience, a resist material having greater etch resistance is needed, but yet unknown in the art. For this reason, a light-shielding film material having a high processing accuracy is needed in order to form a light-shielding film pattern with high resolution. With respect to the light-shielding film material having higher processing accuracy than the prior art materials, there is reported an attempt to incorporate an amount of light element into a chromium compound to accelerate the etching rate of a light-shielding film.

For example, Patent Document 1 discloses a material based on chromium (Cr) and nitrogen (N) and exhibiting, on X-ray diffractometry, diffraction peaks substantially assigned to CrN (200). When a light-shielding film made of this material is processed by chlorine-based dry etching, the dry etching rate is increased, and the film thickness loss of resist film during dry etching is reduced.

Patent Document 2 discloses a photomask blank having a light-shielding film of a chromium-based compound composition which is changed to a light element rich, low chromium composition as compared with the prior art film. That is, the composition, film thickness and laminate structure are appropriately designed so as to gain a desired transmittance T and reflectivity R while accelerating dry etching.

When a light-shielding film material based on a chromium-based compound and having light element added thereto is used, the light-shielding film must be designed such that not only its etching rate is improved, but also necessary optical properties are ensured, because it is an optical film. This imposes a limit to the freedom of film design. Also when a chromium-based compound having light element added thereto is used as a hard mask film, but not as a light-shielding film, the hard mask film being used for processing of the light-shielding film, the range of available light elements that ensure the necessary functions is duely limited. The freedom of film design is limited in this case too.

### CITATION LIST

Patent Document 1: WO 2007/074806

Patent Document 2: JP-A 2007-033470

Patent Document 3: JP-A H07-140635

Patent Document 4: JP-A 2007-241060

Patent Document 5: JP-A 2007-241065 (US 20070212619)

Patent Document 6: JP-A 2011-149093

### DISCLOSURE OF INVENTION

Aiming to accelerate the etching rate of a functional film, typically a light-shielding film in a photomask blank, while maintaining necessary physical properties including optical properties, the inventors studied a functional film of a chromium-based material containing a metal element having a melting point of not higher than 400° C.

In the manufacture of photomask blanks, it is a common practice to deposit a functional film, typically light-shielding film, by sputtering. When a functional film of a chromium-based material containing a metal element having a melting point of not higher than 400° C. is deposited by sputtering, for example, the following methods can be used:
(1) a sputtering method using a single target prepared by sintering a mixture of chromium or chromium compound with a metal element having a melting point of not higher than 400° C.,
(2) a sputtering method using a single composite target in which chromium and a metal element having a melting point of not higher than 400° C. are disposed in a single backing plate such that the area ratio of these different metals may remain unchanged in a depth direction, and
(3) a co-sputtering method using a target of chromium or chromium compound and a target of a metal element having a melting point of not higher than 400° C.

Of these sputtering methods, method (1) suffers from the problem that target preparation is technically difficult. When particulate chromium or chromium compound and a certain amount of particulate metal element having a melting point of not higher than 400° C. are mixed and sintered, the sintering temperature must be lower than the melting point (≦400° C.) of the metal element for the reason that at a temperature in excess of the melting point of the metal element, the metal element particles are melted into a liquid phase. Such a low sintering temperature may result in an insufficient sintered density or a non-uniform compositional distribution.

With method (2), the target per se can be prepared. However, the target must be prepared for every desired one of functional film compositions because the compositional ratio of chromium to the metal element having a melting point of not higher than 400° C. is fixed. Method (2) cannot flexibly accommodate for any compositional change to meet a change of film design. In addition, method (2) is difficult to deposit a compositionally graded film in which the compositional ratio of chromium to a metal element having a melting point of not higher than 400° C. is continuously varied in a thickness direction.

In contrast, the co-sputtering method (3) can flexibly accommodate for any compositional change and offer a high freedom of film design because chromium and the metal element having a melting point of not higher than 400° C. are available from individual targets, i.e., a target of chromium or chromium compound and a target of the metal element having a melting point of not higher than 400° C., which are subjected to co-sputtering. It is also possible to deposit a compositionally graded film in which the compositional ratio of chromium to the metal element having a melting point of not higher than 400° C. is continuously varied in a thickness direction. In the film deposition by co-sputtering, however, the initial discharging behavior of the target of the metal element having a melting point of not higher than 400° C. is unstable, which necessitates preliminary sputtering until the discharging behavior becomes stable. Even after the discharging behavior becomes stable, the target of the metal element having a melting point of not higher than 400° C. has a high probability of abnormal discharge, which causes damage to the functional film.

In conjunction with the co-sputtering method using two or more targets, for example, a target of a metal or metalloid element having a melting point of higher than 400° C. (high melting element-containing target), such as chromium target or chromium compound target, and a target of a metal element having a melting point of not higher than 400° C. (low melting element-containing target), an object of the invention is to provide a sputter deposition method and a sputtering system capable of sustaining stable co-sputtering; a method for manufacturing a photomask blank using the sputter deposition method or sputtering system; and a photomask blank manufactured using the sputter deposition method or sputtering system.

In the co-sputtering method of depositing a film by simultaneously subjecting a plurality of targets to electric discharge, it is believed an insignificant problem that sputtered particles ejected from one target land on another target, because the once landed sputtered particles are removed by sputtering of the other target. However, where the sputtering rate of the material of the other target is extremely lower than the sputtering rate of the material of the landed sputtered particles, problems arise with the progress of sputtering, namely, the sputtered particles accumulate to form a coating, the sputtering rate of the other target is retarded, the composition of a film resulting from sputter deposition changes, and the deposition rate significantly changes. It then becomes quite difficult to control the composition of a sputter deposition film. In some cases, the sputter surface of the target becomes significantly irregular, which causes abnormal discharge. As a consequence, the sputter surface can become a dust generating source.

Further, if a coating depositing on the sputter surface of the other target is an insulating film, the portion having received the insulating film experiences a charge buildup, which causes abnormal discharge. The sputtering rate is extremely reduced in the insulating film portion. This phenomenon becomes outstanding particularly in DC sputtering and is likely in reactive sputtering using a reactive gas like oxygen or nitrogen as the sputtering gas. In particular, the sputtering using oxygen as the reactive gas has a strong likelihood of forming an insulating film.

Making extensive investigations to solve the above problem, the inventors found that the quality of a film formed is inconsistent in the course of film deposition by co-sputtering because sputtered particles from a plurality of targets during co-sputtering cause mutual contamination or modification to the sputter surfaces of the respective targets, whereby the states of the sputter surfaces are altered. Particularly when the powers supplied to the respective targets have deviations, the target receiving a lower power supply is more liable to contamination or modification on the sputter surface with sputtered particles flying from the target receiving a higher power supply. When the conductivity of a coating formed as a result of sputtered particles flying from one target depositing on the sputter surface of the other target is lower than the conductivity of the other target itself, or when the sputtering rate of the material of the coating is lower than the sputtering rate of the material of the other target, contamination or modification of the sputter surface takes place, interfering with stable sputtering process.

For a target whose surface state has changed, contaminants or modified portions on its sputter surface can be removed, for example, by sputtering the target in an atmosphere solely of an inert gas such as Ar. However, since the sputtering rate is extremely decelerated by contaminants, removal of contaminants or modified portions on the sputter surface is not easy. Even if the removal of contaminants or modified portions is periodically carried out by the above method in order to continue co-sputtering, it is not easy to expose only the target-constituting material over the entire sputter surface of the target to sustain stable and uniform sputtering. Once the state of the sputter surface of the target is altered, it is difficult to completely clean the sputter surface by the above method. There exists a need for means of substantially inhibiting contamination or modification of the sputter surface.

Herein, a target of a metal or metalloid element having a melting point of higher than 400° C., such as chromium target or chromium compound target, is referred to as “high melting element-containing target”, and a target of a metal element having a melting point of not higher than 400° C. is referred to as “low melting element-containing target.” If sputtered particles from the low melting element-containing target fly and land on the supper surface of the high melting element-containing target, sputtered particles from the low melting element-containing target are unlikely to deposit or accumulate (i.e., unlikely to form a coating) on the sputter surface of the high melting element-containing target because the sputtering rate of the material of the sputtered particles from the low melting element-containing target is higher than the sputtering rate of the material of the high melting element-containing target. It is then believed that the discharge of the high melting element-containing target becomes steady from the beginning.

On the other hand, the initial discharge behavior of the low melting element-containing target is unstable because the sputtering rate of the material of the sputtered particles from the high melting element-containing target is lower than the sputtering rate of the material of the low melting element-containing target. Then sputtered particles from the high melting element-containing target is likely to accumulate to form a coating on the sputter surface of the low melting element-containing target. For this reason, the discharge behavior does not become steady until formation of this coating and sputtering of the high melting element-containing target are equilibrated. This coating on the low melting element-containing target gives trigger to induce abnormal discharge.

With respect to a co-sputtering process using two or more targets, for example, a first target and a second target different from the first target, the inventors have found that by providing a common vacuum chamber with the first and second targets such that the surfaces of the first and second targets to be sputtered may face a substrate to be coated and be arranged parallel or oblique to each other, simultaneously supplying electric powers to the first and second targets, and depositing sputtered particles on the substrate while controlling sputtering conditions of the first and second targets such that the rate at which sputtered particles ejected from one target reach the sputter surface of the other target and deposit thereon is not more than the rate at which the sputtered particles are removed from the other target by sputtering thereof, stable co-sputtering can be sustained while inhibiting the sputter surfaces from contamination or modification. Better results are obtained when a barrier member for permanently separating the space defined between the sputter surfaces of the first and second targets is disposed relative to the first and second targets so as to prevent sputtered particles ejected from one target from reaching the sputter surface of the other target. This ensures the formation of a functional film with minimal defects and hence, the manufacture of a photomask blank of quality meeting the miniaturization requirements of circuit patterns.

Accordingly, in a first aspect, the invention provides a method for sputter depositing a film on a substrate, comprising the steps of:

providing a vacuum chamber with first and second targets such that the surfaces of the first and second targets to be sputtered may face a substrate to be coated and be arranged parallel or oblique to each other,

simultaneously supplying electric powers to the first and second targets, and

depositing sputtered particles on the substrate while controlling sputtering conditions of the first and second targets such that the rate at which sputtered particles ejected from one target reach the sputter surface of the other target and deposit thereon is not more than the rate at which the sputtered particles are removed from the other target by sputtering thereof.

In a preferred embodiment, for either one or both of the first and second targets, the resistivity of sputtered particles depositing on the sputter surface of the other target is higher than the resistivity of the other target, or the sputtering rate of the material of which sputtered particles depositing on the sputter surface of the other target are composed is lower than the sputtering rate of the material of which the other target is composed.

In a preferred embodiment, a barrier member for permanently separating the space defined between the sputter surfaces of the first and second targets is disposed relative to the first and second targets so as to prevent sputtered particles ejected from one target from reaching the sputter surface of the other target. The barrier member is preferably disposed in a region where it intersects all straight lines connecting any arbitrary point on the sputter surface of the first target and any arbitrary point on the sputter surface of the second target. More preferably, the barrier member is secured immobile within the vacuum chamber. The barrier member is typically made of a conductive material and electrically grounded.

In a preferred embodiment, the first and second targets are targets of different constituent elements, targets of different compositions of identical constituent elements, or targets having different sputtering rates. In a more preferred embodiment, a combination of a low-melting element-containing target of a material containing a metal with a melting point of not higher than 400° C. with a high-melting element-containing target of a material containing a metal or metalloid with a melting point of higher than 400° C. is used as the first and second targets. Most often, the metal or metalloid with a melting point of higher than 400° C. is chromium, and the metal with a melting point of not higher than 400° C. is tin.

In a preferred embodiment, the sputtering is reactive sputtering using a reactive gas as the sputtering gas. Preferably the reactive gas comprises an oxygen-containing gas.

In a second aspect, the invention provides a sputtering system comprising a vacuum chamber, in which a substrate to be coated is disposed; first and second targets disposed in the vacuum chamber such that the surfaces of the first and second targets to be sputtered may face the substrate and be tilted to each other; and a barrier member for permanently separating the space defined between the sputter surfaces of the first and second targets, disposed relative to the first and second targets so as to prevent sputtered particles ejected from one target from reaching the sputter surface of the other target.

In a preferred embodiment, the barrier member is disposed in a region where it intersects all straight lines connecting any arbitrary point on the sputter surface of the first target and any arbitrary point on the sputter surface of the second target. More preferably, the barrier member is secured immobile within the vacuum chamber. The barrier member is typically made of a conductive material and electrically grounded.

In a third aspect, the invention provides a method for manufacturing a photomask blank, comprising the step of depositing a functional film on a transparent substrate using the sputter deposition method defined above.

In a fourth aspect, the invention provides a method for manufacturing a photomask blank having at least one functional film deposited on a quartz substrate, comprising the steps of:

furnishing the sputtering system defined above,

providing the sputtering system with a target of a material containing a metal with a melting point of not higher than 400° C. and another target of a material containing a metal or metalloid with a melting point of higher than 400° C.,

simultaneously supplying electric powers to both the targets, and

sputter depositing a functional film on the quartz substrate, the functional film containing the metal with a melting point of not higher than 400° C. and the metal or metalloid with a melting point of higher than 400° C.

In a fifth aspect, the invention provides a photomask blank having at least one functional film deposited on a quartz substrate, wherein the functional film contains a metal with a melting point of not higher than 400° C. and a metal or metalloid with a melting point of higher than 400° C., and the functional film is formed by using the sputtering system defined above, providing the sputtering system with a target of a material containing the metal with a melting point of not higher than 400° C. and another target of a material containing the metal or metalloid with a melting point of higher than 400° C., and simultaneously supplying electric powers to both the targets for effecting sputter deposition.

Also contemplated herein is a photomask blank prepared by this method.

### Advantageous Effects of Invention

In film deposition by a co-sputtering process using two or more targets and adapted to easily comply with any change of film composition, a film can be deposited by sputtering with stable discharge while inhibiting mutual contamination or modification of sputter surfaces of the targets. A photomask blank of quality having a substantially defect-free functional film can be consistently manufactured.

### BRIEF DESCRIPTION OF DRAWINGS

FIG. 1 is a schematic cross-sectional view of a sputtering system in one embodiment of the invention.

FIG. 2 is a schematic cross-sectional view of a sputtering system in another embodiment of the invention.

FIG. 3 is a diagram showing current versus power to targets in Examples 1 and 2 and Comparative Examples 1 to 3.

FIG. 4 is a diagram showing chamber pressure versus target power in Examples 1 and 2 and Comparative Examples 1to 3.

FIG. 5 is a schematic cross-sectional view of a prior art sputtering system in Comparative Examples.

In the disclosure, like reference characters designate like or corresponding parts throughout the several views shown in the figures.

### DESCRIPTION OF PREFERRED EMBODIMENTS

As used herein, the terms “first,” “second,” and the like do not denote any order or importance, but rather are used to distinguish one element from another. The terms “conductive” and “insulating” are electrically conductive and electrically insulating.

One embodiment of the invention is a method for sputter depositing a film on a substrate. It is a co-sputtering process involving the steps of providing a common vacuum chamber with first and second targets such that the sputter surfaces of the first and second targets may face a substrate to be coated and be arranged parallel or oblique to each other, and simultaneously supplying electric powers to the first and second targets. As used herein, the term “sputter surface” refers to a surface of a target from which particles are ejected during sputtering.

The first and second targets are not limited to targets of two species. When targets of three or more species are used, targets of any two species are taken as first and second targets. When targets of three or more species are used, there are plural combinations of targets of two species. It suffices that the relationship of first and second targets according to the invention applies to at least one combination, preferably all combinations. The number of targets for each species is not limited to one, and a plurality of targets of identical species may be used. The sputter surfaces of first and second targets are arranged parallel or oblique to each other. The angle included between the sputter surfaces is generally 60° to 180°, preferably 90° to 170°.

In the sputter deposition method of the invention, the first and second targets are sputtered while controlling sputtering conditions such that the rate at which sputtered particles ejected from one target reach the sputter surface of the other target and deposit thereon is not more than the rate at which the sputtered particles deposited on the sputter surface of the other target are removed therefrom when the other target is sputtered, whereby sputtered particles are deposited on the substrate to form a coating thereon. This way of control ensures that even when sputtered particles ejected from one target reach the sputter surface of the other target and deposit thereon, the sputtered particles deposited on the other target are successively removed therefrom as the other target is sputtered. Stable co-sputtering sustains while contamination or modification of the sputter surfaces is inhibited.

As the effective means of controlling the deposition rate of sputtered particles to be not higher than the removal rate of sputtered particles during the co-sputtering process, a barrier member for permanently separating the space defined between the sputter surfaces of the first and second targets is disposed relative to the first and second targets so as to prevent sputtered particles ejected from one target from reaching the sputter surface of the other target. This inhibits sputtered particles ejected from one target from reaching the sputter surface of the other target and depositing thereon. Then the deposition rate of sputtered particles is kept not higher than the removal rate of sputtered particles during the co-sputtering process, even under the situation that the resistivity of sputtered particles depositing on the sputter surface of the other target is higher than the resistivity of the other target, or the sputtering rate of the material of which sputtered particles depositing on the sputter surface of the other target are composed is lower than the sputtering rate of the material of which the other target is composed, that is, under the condition that sputtered particles deposited on the sputter surface of the other target or a coating formed as a result of sputtered particles accumulating thereon is removed with difficulty in the prior art co-sputtering process.

Preferably, the barrier member is arranged so as to intersect all straight lines connecting any arbitrary point on the sputter surface of the first target and any arbitrary point on the sputter surface of the second target. With this arrangement, sputtered particles ejected from the sputter surface of one target and moving straight toward the sputter surface of the other target are surely blocked by the barrier member. Although it suffices that the barrier member is arranged only in the region where the barrier member intersects all straight lines connecting any arbitrary point on the sputter surface of the first target and any arbitrary point on the sputter surface of the second target, the barrier member may be extended beyond the region where the barrier member intersects all straight lines connecting any arbitrary point on the sputter surface of the first target and any arbitrary point on the sputter surface of the second target, depending on sputter deposition conditions, especially sputtering pressure, for the reason that as the pressure within the vacuum chamber during sputtering becomes higher, the mean free path of sputtered particles becomes shorter, and the probability of sputtered particles from one target bypassing the barrier member and reaching the sputter surface of the other target becomes higher.

The barrier member is disposed to permanently separate the space defined between the sputter surfaces of the first and second targets. Preferably the barrier member is secured immobile within the vacuum chamber, because the amount of dust generation increases if it has any mobile section.

The barrier member is preferably formed of a conductive material. Also preferably it is electrically grounded. Although the barrier member may be kept electrically floating or non-grounded, preferably the barrier member is electrically connected to a grounded portion (e.g., grounded vacuum chamber or grounded vacuum chamber barrier) of the sputtering system for thereby preventing any charge buildup on the barrier member.

Sputtered particles ejected from the targets impinge the barrier member. If the barrier member includes an angled portion where sputtered particles impinge, then a coating forms as sputtered particles deposit and accumulate on the barrier member and such coating is liable to spall off. Since fragments spalling off the coating cause defects to the sputtered film, preferably the barrier member does not include any angled or sharp portion where sputtered particles impinge. Specifically, better results are obtained when the corner or tip of the barrier member is tapered or rounded.

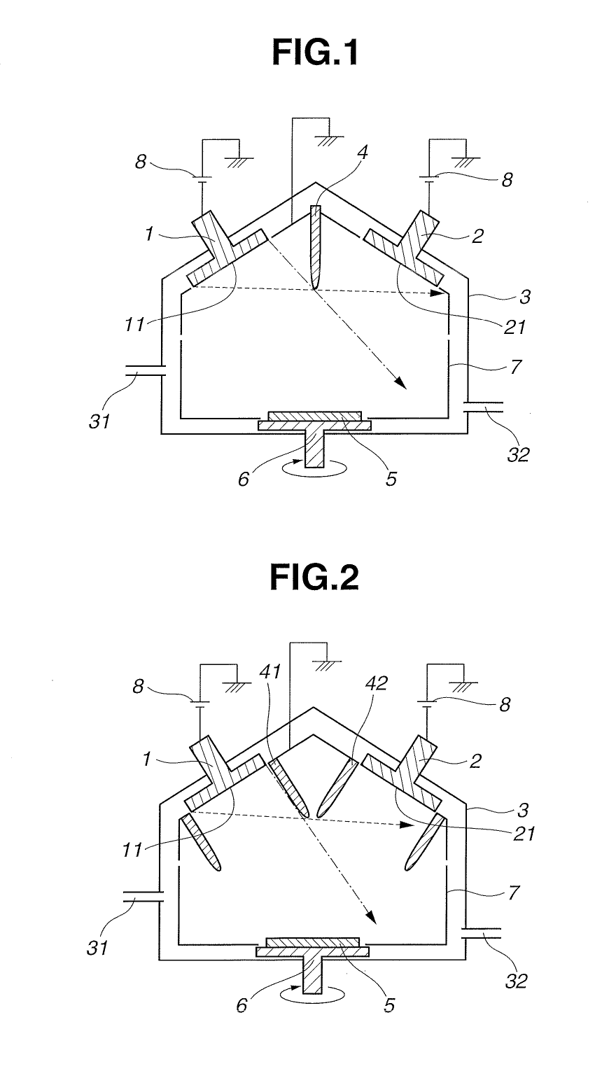

Referring to FIG. 1, there is illustrated a sputtering system which is suited in the practice of the sputter deposition method of the invention. The sputtering system of FIG. 1 is a DC sputtering system comprising a first target 1 and a second target 2 disposed in a common vacuum chamber 3. A substrate 5 to be coated (i.e., subject to sputter deposition) is disposed in the chamber 3. The first target 1 to has an inside surface 11 to be sputtered and the second target 2 has an inside surface 21 to be sputtered. The first and second targets 1 and 2 are arranged such that their sputter surfaces 11 and 21 may face the substrate 5. The first and second targets 1 and 2 are also arranged such that their sputter surfaces 11 and 21 may face inside and be oblique to each other. The substrate 5 is rested on a holder 6 which is adapted to rotate so that the sputter film-receiving surface of the substrate 5 may spin about the axis.

Also disposed in the vacuum chamber 3 of the sputtering system is a barrier member 4 for permanently separating the space defined between the sputter surfaces 11 and 21 of the first and second targets 1 and 2. The barrier member 4 is a plate including a lower portion which is tapered toward the lower tip. The lower tip of the barrier member 4 is rounded in cross section. The barrier member 4 is secured immobile within the vacuum chamber 3. Also a shield 7 is extended along the inner wall of the vacuum chamber 3. The vacuum chamber shield 7 is electrically grounded while the barrier member 4 is connected to the shield 7 and thus electrically grounded via the shield 7. Also illustrated in FIG. 1 are a sputtering gas inlet 31, exhaust outlet 32, and DC power supplies 8.

The barrier member 4 is disposed in a region where it intersects all straight lines connecting any arbitrary point on the sputter surface 11 of the first target 1 and any arbitrary point on the sputter surface 21 of the second target 2. Herein, reference is made to the side of first target 1, for example. Sputtered particles are ejected in random directions according to the cosine rule. The upper limit positions of sputtered particles ejected from the circumferential edge of sputter surface 11 of first target 1 are depicted by the broken line arrows in FIG. 1. Those sputtered particles ejected from the circumferential edge of sputter surface 11 of first target 1 and moving straight toward sputter surface 21 of second target 2, whether they come from a top side (nearer to second target) or a bottom side (remote from second target), are blocked by barrier member 4, indicating that they cannot reach sputter surface 21 of second target 2. This is also true on the side of second target 2.

FIG. 2 illustrates another sputtering system which is also suited to carry into practice the sputter deposition method of the invention. In the sputtering system of FIG. 2, cylindrical barrier members 41 and 42 for permanently separating the space defined between the sputter surfaces 11 and 21 of the first and second targets 1 and 2 are disposed so as to surround the sputter surfaces 11 and 21 of first and second targets 1 and 2, respectively. Each of the barrier members 41 and 42 includes a lower portion which is tapered toward the lower tip. The lower tip of the barrier member is rounded in cross section. The barrier members 41 and 42 are secured immobile within the vacuum chamber 3. The barrier members 41 and 42 are connected to the vacuum chamber shield 7 and thus electrically grounded via the shield 7. Notably, the sputtering system of FIG. 2 is the same as that of FIG. 1 except that the barrier members are different, with like characters representing like parts.

Each of barrier members 41 and 42 is arranged in a region where it intersects all straight lines connecting any arbitrary point on the sputter surface 11 of the first target 1 and any arbitrary point on the sputter surface 21 of the second target 2. Herein, reference is made to the side of first target 1, for example. Sputtered particles are ejected in random directions according to the cosine rule. The upper limit positions of sputtered particles ejected from the circumferential edge of sputter surface 11 of first target 1 are depicted by the broken line arrows in FIG. 2. Those sputtered particles ejected from the circumferential edge of sputter surface 11 of first target 1 and moving straight toward sputter surface 21 of second target 2, whether they come from a top side (nearer to second target) or a bottom side (remote from second target), are blocked by barrier member 41, indicating that they cannot reach sputter surface 21 of second target 2. This is also true on the side of second target 2 in that those sputtered particles ejected from second target 2 are blocked by barrier member 42 before they reach sputter surface 11 of first target 1.

In either of the systems of FIGS. 1 and 2, provision is made for the first and second targets such as to prevent sputtered particles ejected from one target from reaching the sputter surface of the other target, that is, to prevent sputtered particles ejected from first target 1 from reaching the sputter surface 21 of second target 2 and sputtered particles ejected from second target 2 from reaching the sputter surface 11 of first target 1.

The barrier member is configured as a plate in FIG. 1 and a cylinder in FIG. 2, but not limited thereto. While FIGS. 1 and 2 illustrate exemplary DC sputtering systems, the sputter deposition method of the invention may be an RF sputtering method and the sputtering system of the invention may be an RF sputtering system. The invention is equally effective in DC sputter deposition methods such as DC magnetron sputter deposition and pulse DC sputter deposition methods, and in DC sputtering systems such as DC magnetron sputtering and pulse DC sputtering systems.

The invention is effective when a combination of first and second targets, that is, a combination of a first target and a second target of different species is a combination of targets of different constituent elements or different compositions of identical constituent elements. The invention is also effective when a combination of first and second targets is a combination of targets having different sputtering rates. This is because co-sputtering from a combination of first and second targets of different species tends to give rise to a phenomenon that sputtered particles ejected from one target deposit on the sputter surface of the other target to form a coating thereon.

Accordingly, the invention is effective when a combination of first and second targets is a combination of a low melting element-containing target containing a metal element with a melting point of not higher than 400° C., specifically a target formed of a material with a melting point of not higher than 400° C., and more specifically a target formed of a metal with a melting point of not higher than 400° C., with a high melting element-containing target containing a metal or metalloid with a melting point of higher than 400° C., specifically a target formed of a material with a melting point of higher than 400° C., and more specifically a target formed of a metal or metalloid with a melting point of higher than 400° C.

Examples of the low melting element-containing target include targets made of materials containing a metal with a melting point of not higher than 400° C. (referred to as low melting metal), such as In, Sn or Ga. The low melting element-containing target preferably has a melting point of not higher than 400° C. Specifically, an In target, Sn target, and Ga target are useful. Examples of the high melting element-containing target include targets made of materials containing a metal or metalloid with a melting point of higher than 400° C. (referred to as high melting metal), such as Al, Ti, Cr, Ni, Mo, Au or Si. The high melting element-containing target preferably has a melting point of higher than 400° C. Specifically, an Al target, Ti target, Cr target, Ni target, Mo target, Au target, Si target, and MoSi target are useful. Inter alia, the low melting metal is preferably In or Sn, with Sn being most preferred, and the high melting metal is preferably Cr, Mo, or Si, with Cr being most preferred.

Although the sputter deposition method and sputtering system of the invention may be used in deposition using only an inert gas such as Ar, Ne or Kr, they are more effective in reactive sputtering in an atmosphere containing a reactive gas, for example, an oxygen-containing gas, nitrogen-containing gas or carbon-containing gas such as O₂ gas, O₃ gas, N₂ gas, N₂O gas, NO gas, NO₂ gas, CO gas or CO₂ gas, or an atmosphere containing both the reactive gas and inert gas. The invention becomes advantageous particularly when the atmosphere contains oxygen-containing gas as the reactive gas, because sputtered particles depositing on the sputter surface of a target become oxide particles which are insulating in most cases.

The sputter deposition method and sputtering system of the invention are adequate as a method for depositing a functional film in the manufacture of a photomask blank comprising a transparent substrate such as quartz substrate and at least one functional film stacked thereon. Examples of the functional film formed on a transparent substrate include a light-shielding film, antireflection film, phase shift film, etch mask film, and etch stop film, especially an optical film having predetermined optical properties such as a light-shielding film, antireflection film, or phase shift film. The sputter deposition method and sputtering system of the invention are suited for depositing any of these functional films, specifically optical films, and especially a light-shielding film. Using the sputter deposition method and sputtering system of the invention, a functional film substantially free of defects can be deposited, and hence, a photomask blank of quality complying with the miniaturization of circuit pattern can be manufactured.

As compared with the functional film whose metal or metalloid component consists of a high melting metal with a melting point of higher than 400° C., a functional film containing a high melting metal with a melting point of higher than 400° C. and a certain amount of a low melting metal with a melting point of not higher than 400° C. is expected to improve in etching rate. Using the sputter deposition method and sputtering system of the invention, a functional film containing both a high melting metal and a low melting metal can be deposited by stable co-sputtering while minimizing dust generation in the sputtering system.

From the aspect of accelerating the etching rate of a functional film in a photomask blank, the preferred combination of first and second targets is a combination of a low melting element-containing target of a material containing at least one of In and Sn, with a high melting element-containing target of a material containing a metal or metalloid selected from Cr, Mo and Si, especially a material containing Cr. Specifically, a combination of an In target with a Cr target and a combination of a Sn target with a Cr target are preferred.

### EXAMPLE

Examples and Comparative Examples are given below by way of illustration and not by way of limitation.

### Examples 1 and 2

There were furnished a DC magnetron sputtering system as shown in FIG. 1, a Sn target as the first target, a Cr target as the second target, Ar inert gas and N₂ and O₂ reactive gases as the sputtering gas. A conductive plate of 150 mm high by 500 mm wide was used as the barrier member between the targets and aligned with a perpendicular bisector to a line segment connecting the centers of sputter surfaces of two targets. The barrier member is arranged in a region where it intersects all straight lines connecting any arbitrary point on the sputter surface of the Sn target and any arbitrary point on the sputter surface of the Cr target. The substrate used was a 6025 quartz substrate for photomasks, on which a CrSnON film was deposited.

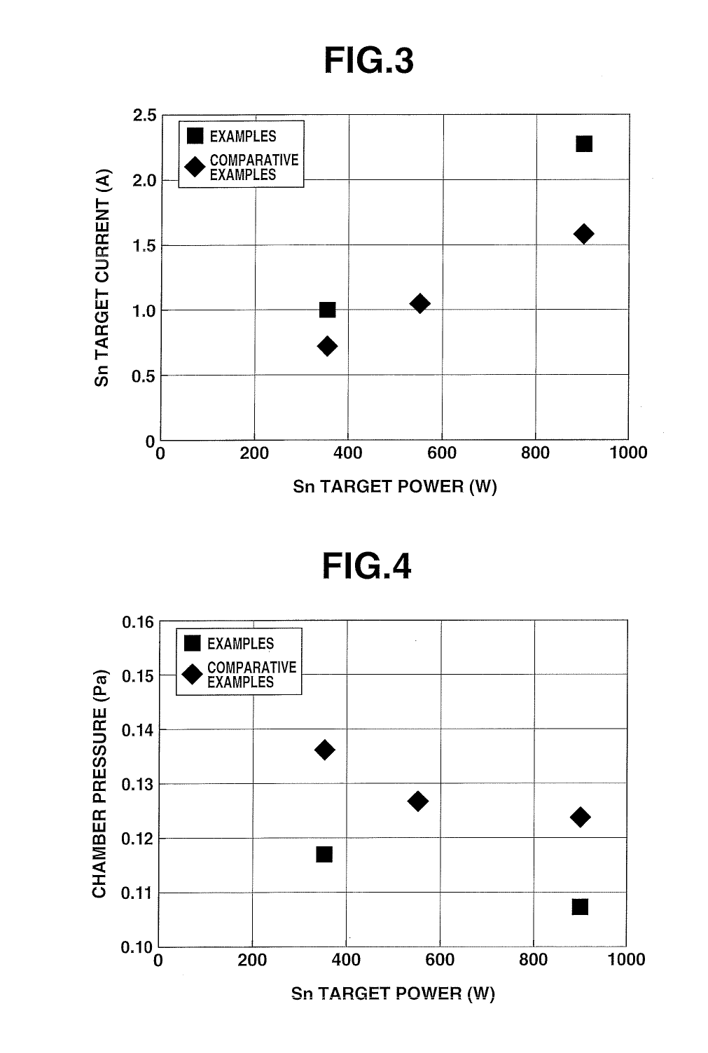

With respect to discharge, the power is constant, the current and voltage values to each target change depending on the sputtering environment. The power to the Cr target was fixed at 1,000 W, and the power to the Sn target was 350 W (in Example 1) or 900 W (in Example 2). At the time when film deposition became stable or assumed the steady state, the current value (voltage value) on the Sn target and the vacuum of the vacuum chamber were evaluated. The results are plotted in FIGS. 3 and 4.

### Comparative Examples 1 to 3

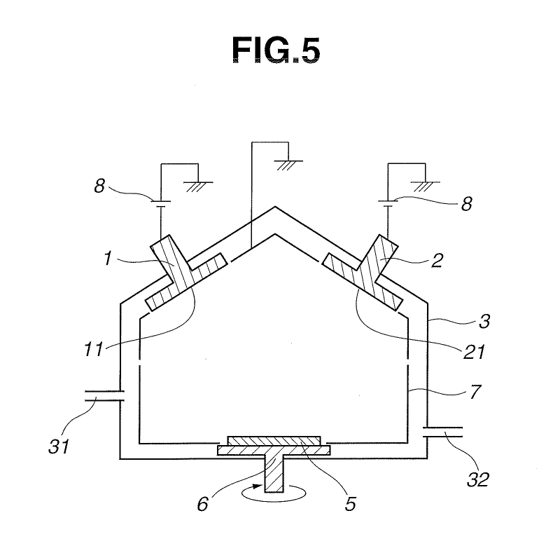

A CrSnON film was deposited on a quartz substrate as in Example 1 except that a barrier-free sputtering system as illustrated in FIG. 5 was used, and the power to the Sn target was 350 W (in Comparative Example 1), 550 W (in Comparative Example 2), or 900 W (in Comparative Example 3). The current value (voltage value) on the Sn target and the vacuum of the vacuum chamber were evaluated. The results are plotted in FIGS. 3 and 4. Notably, the sputtering system of FIG. 5 is the same as in FIG. 1 except that the barrier member is omitted, with like characters representing like parts.

A comparison of Examples 1 and 2 with Comparative Examples 1 to 3 shows that a higher current value (i.e., lower voltage value) is available in Examples using the barrier member than in Comparative Examples omitting the barrier member. The pressure of the vacuum chamber is reduced in Examples using the barrier member because more of the reactive gas is consumed. It is thus believed that sputtered particles are released richer in Examples using the barrier member than in Comparative Examples omitting the barrier member. It is evident from these results that when a barrier member is interposed between targets, a voltage rise on the targets caused by the influence of contamination or modification of the sputter surfaces of targets can be suppressed, that is, the occurrence of abnormal discharge be suppressed. As a result, a substantially defect-free film is formed.

The deposition rate and film composition are compared between Example 1 and Comparative Example 1. As seen from a comparison between Example 1 and Comparative Example 1, when sputter deposition was continued for an identical time (250 seconds), a film of 34 nm thick deposited in Comparative Example 1 with the barrier member omitted, and a film of 53 nm thick deposited in Example 1 with the barrier member, indicating that the deposition rate in Example 1 was increased by a factor of 1.5 over Comparative Example 1. The composition of the thus deposited film was analyzed by x-ray photoelectron spectroscopy (XPS). As seen from the results of XPS, the film of Comparative Example 1 deposited without the barrier member had a Sn/Cr atomic ratio of 0.32 whereas the film of Example 1 deposited using the barrier member had a Sn/Cr atomic ratio of 0.49, indicating an increase of Sn relative to Cr. It is thus believed that the tin content is increased by interposing the barrier member because a lowering of sputtering efficiency of targets is suppressed and the sputtering rate of Sn target which is sensitive to the impact of depositing sputtered particles is maintained.

Japanese Patent Application No. 2013-253099 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A method for sputter depositing a film on a substrate, comprising the steps of:
providing a vacuum chamber with first and second targets such that the surfaces of the first and second targets to be sputtered may face a substrate to be coated and be arranged parallel or oblique to each other,
simultaneously supplying electric powers to the first and second targets, and
depositing sputtered particles on the substrate while controlling sputtering conditions of the first and second targets such that the rate at which sputtered particles ejected from one target reach the sputter surface of the other target and deposit thereon is not more than the rate at which the sputtered particles are removed from the other target by sputtering thereof.

2. The method of claim 1 wherein for either one or both of the first and second targets, the resistivity of sputtered particles depositing on the sputter surface of the other target is higher than the resistivity of the other target, or the sputtering rate of the material of which sputtered particles depositing on the sputter surface of the other target are composed is lower than the sputtering rate of the material of which the other target is composed.

3. The method of claim 1 wherein a barrier member for permanently separating the space defined between the sputter surfaces of the first and second targets is disposed relative to the first and second targets so as to prevent sputtered particles ejected from one target from reaching the sputter surface of the other target.

4. The method of claim 3 wherein the barrier member is disposed in a region where it intersects all straight lines connecting any arbitrary point on the sputter surface of the first target and any arbitrary point on the sputter surface of the second target.

5. The method of claim 3 wherein the barrier member is secured immobile within the vacuum chamber.

6. The method of claim 3 wherein the barrier member is made of a conductive material and electrically grounded.

7. The method of claim 1 wherein the first and second targets are targets of different constituent elements, targets of different compositions of identical constituent elements, or targets having different sputtering rates.

8. The method of claim 1 wherein a combination of a low-melting element-containing target of a material containing a metal with a melting point of not higher than 400° C. with a high-melting element-containing target of a material containing a metal or metalloid with a melting point of higher than 400° C. is used as the first and second targets.

9. The method of claim 8 wherein the metal or metalloid with a melting point of higher than 400° C. is chromium.

10. The method of claim 8 wherein the metal with a melting point of not higher than 400° C. is tin.

11. The method of claim 1 wherein the sputtering is reactive sputtering using a reactive gas as the sputtering gas.

12. The method of claim 11 wherein the reactive gas comprises an oxygen-containing gas.

13. A sputtering system comprising
a vacuum chamber, in which a substrate to be coated is disposed,
first and second targets disposed in the vacuum chamber such that the surfaces of the first and second targets to be sputtered may face the substrate and be tilted to each other, and
a barrier member for permanently separating the space defined between the sputter surfaces of the first and second targets, disposed relative to the first and second targets so as to prevent sputtered particles ejected from one target from reaching the sputter surface of the other target.

14. The system of claim 13 wherein the barrier member is disposed in a region where it intersects all straight lines connecting any arbitrary point on the sputter surface of the first target and any arbitrary point on the sputter surface of the second target.

15. The system of claim 13 wherein the barrier member is secured immobile within the vacuum chamber.

16. The system of claim 13 wherein the barrier member is made of a conductive material and electrically grounded.

17. A method for manufacturing a photomask blank, comprising the step of depositing a functional film on a transparent substrate using the sputter deposition method of claim 1.

18. A method for manufacturing a photomask blank having at least one functional film deposited on a quartz substrate, comprising the steps of:
furnishing the sputtering system of claim 13,
providing the sputtering system with a target of a material containing a metal with a melting point of not higher than 400° C. and another target of a material containing a metal or metalloid with a melting point of higher than 400° C.,
simultaneously supplying electric powers to both the targets, and
sputter depositing a functional film on the quartz substrate, the functional film containing the metal with a melting point of not higher than 400° C. and the metal or metalloid with a melting point of higher than 400° C.

19. A photomask blank having at least one functional film deposited on a quartz substrate, wherein
the functional film contains a metal with a melting point of not higher than 400° C. and a metal or metalloid with a melting point of higher than 400° C., and
the functional film is formed by using the sputtering system of claim 13, providing the sputtering system with a target of a material containing the metal with a melting point of not higher than 400° C. and another target of a material containing the metal or metalloid with a melting point of higher than 400° C., and simultaneously supplying electric powers to both the targets for effecting sputter deposition.

20. A photomask blank prepared by the method of claim 17.
